(19) United States
(12) Patent Application Publication
(10) Pub. No.: US 2026/0314107 A1
(43) Pub. Date: Oct. 8, 2026

(54) MANUFACTURABLE TOPOLOGICAL OPTIMIZATION OF METALLIZATION FOR INCREASED DURABILITY OF PHOTOVOLTAIC (PV) MOLECULES AGAINST EXTREME WEATHER EVENTS

(71) Applicant: UNM RAINFOREST INNOVATIONS, Albuquerque, NM (US)

(72) Inventors: Sang M. HAN, Albuquerque, NM (US); Sang Eon HAN, Albuquerque, NM (US); April JEFFRIES, Albuquerque, NM (US); Leonid MIROSHNIK, Albuquerque, NM (US)

(21) Appl. No.: 19/262,740

(22) PCT Filed: Jan. 9, 2024
(86) PCT No.: PCT/US2024/010936

§ 371 Date: Jul. 8, 2025

Related U.S. Application Data
(60) Provisional application No. 63/479,020, filed on Jan. 9, 2023.

(51) Int. Cl. H10F 77/20; G06F 30/20; H10F 71/00

(52) U.S. Cl. CPC H10F 77/215; G06F 30/20; H10F 71/128

(57) ABSTRACT

A method to topologically optimize metallization used in solar cells is provided. The method includes modeling a solar cell using a steady state current conservation equation; determining a maximum current density for the solar cell being modeled under a predetermined illumination arrangement; extracting a photocurrent density and a dark density from an experimental measurement of a reference solar cell as a function of voltage; and generating a metallization that is topologically optimized based the photocurrent density and a dark density that is extracted and the maximum current density that is determined.

### CROSS-REFERENCE TO RELATED APPLICATIONS

This application is a U.S. National Phase application of PCT/US2024/010936, filed Jan. 9, 2024, which claims the benefit of U.S. Provisional Patent Application No. 63/479,020, filed Jan. 9, 2023, the disclosures of which are incorporated by reference herein in their entireties.

### FIELD

The present disclosure is directed to manufacturable topological optimization of metallization for improved cell and module efficiency, metal usage reduction, and increased durability of PV modules against environmental stressors and extreme weather events.

### BACKGROUND

As extreme weather events, such as hailstorms and hurricanes, are becoming increasingly frequent and severe, the photovoltaic (PV) asset management against these weather events has become a major concern for PV project developers and field owners, particularly, in the affected areas. To illustrate, the hail damage to a solar project in west Texas in 2019 alone cost tens of millions of dollars. These assets are becoming non-insurable or insurable at a much higher cost. For the public, the reduced or interrupted power generation can cause irrecoverable economic loss and even risk to human lives.

FIG. 1A shows hail impact damage to PV modules observed at the National Renewable Energy Laboratory (NREL). Inset of FIG. 1A shows UV fluorescence (UVF) images of a module after hail damage. FIG. 1B shows tracker failure due to heavy wind. Inset of FIG. 1B shows electroluminescence (EL) image of a module after static loading. FIG. 1C shows commonly observed snow load on PV modules. FIG. 1D shows post-typhoon damage.

While some of the damages from extreme weather events are irrecoverable, requiring module replacement and tracker repair, recoverable damages or damages can be mitigated to maintain power generation. For example, cracks appearing in solar cells can lead to power loss over time. As extreme weather events, such as hailstorms and hurricanes, become frequent, the PV industry anticipates cell cracks to significantly add to module degradation in the future. FIG. 1A and FIG. 1B illustrate, by UVF in FIG. 1A and EL in imaging in FIG. 1B, how a static load, such as wind or snow load, and a hailstorm can cause microcracks in solar cells within a PV module.

### SUMMARY

According to examples of the present disclosure, a solar module (also known as PV module) is disclosed that comprises a plurality of solar cells; and one or more gridlines and one or more busbars arranged on solar cells.

Various additional features can be included in the solar cell including one or more of the following features. The one or more gridlines and the one or more busbars provide enhanced fracture toughness, electrical gap-bridging of cracked solar cells, and “self-healing” to regain electrical continuity after many cycles of strain-induced failure. The one or more gridlines and the one or more busbars provide increased tolerance to mechanical stress observed in fielded modules, maximum current collection, resilience to cell cracks that reflect specific weather events (wind/snow load vs. hail impact), and decreased silver usage.

According to examples of the present disclosure, a method for creating gridlines and busbars for a solar cell is disclosed. The method comprises incorporating carbon nanotubes (CNTs) into a silver (Ag) paste to form a metal matrix composite (MMC); screen-printing the MMC paste on a solar cell to form gridlines and busbars; and then firing the printed gridlines and busbars to form metal contacts with the solar cell substrate, wherein the CNTs provide electromechanical reinforcement that preserves the solar module performance in the presence of cracked substrates and fractured metal contacts.

According to examples of the present disclosure, a solar module is disclosed that comprises a plurality of photovoltaic (PV) modules; and one or more gridlines and one or more busbars arranged between the plurality of PV modules, wherein the one or more gridlines and the one or more busbars comprise surface functionalized, multi-walled carbon nanotubes (MW-CNTs) that are combined with silver paste to form metal matrix composites (MMCs).

Various additional features can be included in the solar module including one or more of the following features. The one or more gridlines and the one or more busbars provide enhanced fracture toughness, electrical gap-bridging of cracked solar cells, and “self-healing” to regain electrical continuity after many cycles of strain-induced failure. The one or more gridlines and the one or more busbars provide increased tolerance to mechanical stress observed in fielded modules, maximum current collection, resilience to cell cracks that reflect specific weather events (wind/snow load vs. hail impact), and decreased silver usage.

According to examples of the present disclosure, a method for creating gridlines and busbars for a solar module is disclosed. The method comprises incorporating multi-walled carbon nanotubes (MW-CNTs) into a silver (Ag) paste; and screen-printing the MW-CNTs and the Ag paste and firing onto a substrate, wherein the MW-CNTs provide electromechanical reinforcement that preserves the solar module performance in the presence of cracked substrates and fractured metal contacts, wherein the MW-CNTs-metal composites are formed as metal matrix composites (MMCs).

According to examples of the present disclosure, a method to topologically optimize metallization used in solar cells is provided. The method comprises modeling a solar cell using a steady state current conservation equation; determining a maximum current density for the solar cell being modeled under a predetermined illumination arrangement; extracting a photocurrent density and a dark density from an experimental measurement of a reference solar cell as a function of voltage; and generating a metallization that is topologically optimized based the photocurrent density and a dark density that is extracted and the maximum current density that is determined.

According to examples of the present disclosure, a computer system is provided that comprises a hardware processor; and a non-transitory computer readable storage medium storing instructions that when executed by the hardware processor perform a method to topologically optimize metal matrix composite (MMC) metallization used in solar cells, the method comprising: modeling a solar cell using a steady-state current conservation equation; determining a maximum current density for the solar cell being modeled under a predetermined illumination arrangement; extracting a photocurrent density and a dark density from an experimental measurement of a reference solar cell as a function of voltage; and generating a metallization that is topologically optimized based the photocurrent density and a dark density that is extracted and the maximum current density that is determined.

According to examples of the present disclosure, a solar cell is provided that comprises topologically optimized metallization for gridlines and busbars to maximum efficiency, improved tolerance for observed stress, and resilience to cell cracks and crack patterns.

According to examples of the present disclosure, the method, the computer system, and the solar cell can include one or more of the following additional features. The metallization is topologically optimized using a structural optimization process with one or more multi-physics constraints. The metallization is topologically optimized to improve durability and efficiency and to reduce production costs of silicon PV modules. The metallization is topologically optimized for gridlines and busbars to maximum efficiency, improved tolerance for observed stress, and resilience to cell cracks and crack patterns. The metallization is topologically optimized while maintaining a same or less metal coverage on a cell surface to maximize light absorption and keeping gridline dimensions above the minimum screen-printable features. The metallization comprises surface-functionalized, carbon nanotubes (CNTs). The multi-physics constraints comprise one or more governing device physics parameters and one or more physical parameters. The one or more physical parameters comprise a current density representing minority carrier generation rate, a minority carrier recombination rate, single diode parameters comprising a series and shunt resistance, conductance in emitter. The structural optimization process comprises a solid isotropic material with penalization (SIMP) density model and a gradient-based method of moving asymptotes (MMA) solver. The MMA solver maximizes solar power generated by spatially manipulating a silver volume fraction. The silver volume fraction varies between a pure silicon state and a pure silver state to form an optimized silver-silicon alloy structure. The pure silicon state is set equal zero and the pure silver state is set equal to one. The SIMP density model comprises material and structural parameters. The material and structural parameters comprise electrical conductivity, relative permittivity, and material thickness that vary as a function of one. The structural optimization process comprises a step-function filter to extract discrete silver and silicon domains as a binary choice. The structural optimization process comprises using an optimized gridline structure in simulation to extract cell performance. The method can further comprise screen-printing and firing the optimized gridline structure on solar cells, wherein the solar cells comprise p-type bifacial passivated emitter and rear contact (PERC) solar cells and n-type cells Tunnel Oxide Passivated Contact (TOPCon) solar cells. The metallization comprises a metal matrix composite (MMC).

### BRIEF DESCRIPTION OF THE DRAWINGS

FIG. 1A shows hail impact damage to PV modules observed at NREL. Inset of FIG. 1A shows UVF images of a module after hail damage. FIG. 1B shows tracker failure due to heavy wind. Inset of FIG. 1B shows EL image of a module after static loading. FIG. 1C shows commonly observed snow load on PV modules. FIG. 1D shows post-typhoon damage.

FIG. 2A shows a plot of electrical gap bridging of various MMC pastes according to examples of the present disclosure; FIG. 2B shows a plot of stress vs. strain curves of commercial base line (-) according to examples of the present disclosure; MMC formulation 1 (- - - ) and MMC formulation 2 (- - - ); FIG. 2C shows principal stress magnitudes at the crack tip according to examples of the present disclosure; FIG. 2D shows in situ three-point-bending under scanning electron microscope and fractured gridlines over cell cracks according to examples of the present disclosure; and FIG. 2E shows cyclic mini-module three-point bending test results (courtesy of D2Solar) according to examples of the present disclosure.

FIG. 3A shows a Resistance Across Cleaves and cracks (RACK) setup to measure electrically bridgeable gap in cell cracks and to monitor “self-healing” according to examples of the present disclosure. FIG. 3B shows strain-induced failure and self-healing cycles for MetZilla MMC metallization level off at ~30 μm compared to ~10 μm for standard “baseline” metallization according to examples of the present disclosure.

FIG. 4A shows a standard baseline metallization layout of 5-busbar solar cells according to examples of the present disclosure. A subsection of the cell, outlined by a dotted rectangle, is modeled and optimized. FIG. 4B shows one possible initial condition before topologically optimizing 2-mm-pitch gridline design. The optimized design from this initial condition increases the efficiency by 0.09% and uses 19% less silver according to examples of the present disclosure. FIG. 4C shows a topologically optimized 5-mm-pitch gridline design that increases efficiency by 0.11% and uses 27% less silver according to examples of the present disclosure. FIG. 4D shows a table describing efficiency gains and reduced silver usage from optimized gridline structures according to examples of the present disclosure.

FIG. 5A and FIG. 5B show a conventional rectangular gridline design (FIG. 5A) vs. topologically optimized, image-processed, and image-enhanced gridline design (FIG. 5B) according to examples of the present disclosure. The image processing and enhancement led to undesirable increase in metal laydown weight for the example shown in FIG. 5B.

FIG. 6A and FIG. 6B show a small 2-inch x 2-inch Passivated Emitter and Rear Contact (PERC) cells screen-printed with topologically optimized gridline design according to examples of the present disclosure.

FIG. 7 shows, upon hailstone impact, a schematic diagram of cracked sun-facing front glass (in glass/backsheet or glass/glass construction PV modules) on a solar cell with 5-busbar gridline design.

FIG. 8A shows gridline design topologically optimized to minimize stress, when subjected to a deflection corresponding to 2400 Pa front load according to examples of the present disclosure. FIG. 8B shows a stress profile within the gridlines according to examples of the present disclosure.

FIG. 9A, FIG. 9B, FIG. 9C, and FIG. 9D shows examples of solar cell designs according to examples of the present disclosure.

FIG. 10A, FIG. 10B, FIG. 10C, and FIG. 10D shows time-series progression of topological optimization of a single gridline set between two busbars (i.e., snapshots through time how the topological optimization evolves) according to examples of the present disclosure.

FIG. 11A, FIG. 11B, FIG. 11C, and FIG. 11D shows example dimensional plots for an optimized gridline design according to examples of the present disclosure.

FIG. 12A shows a 7065 μm×7065 μm digitized image of a leaf vein pattern according to examples of the present disclosure. FIG. 12B shows an auto-correlation and a lineal path function extracted from the image according to examples of the present disclosure. FIG. 12C shows three overlapping Voronoi patterns of different line widths according to examples of the present disclosure.

FIG. 13A shows a “Unit cell” of conventional busbar and gridlines. FIG. 13B shows a conventional metallization under stress. FIG. 13C shows a topologically optimized metallization design against stress according to examples of the present disclosure. FIG. 13D shows a reduced stress in topologically optimized metallization according to examples of the present disclosure.

FIG. 14 shows an example of gridlines according to examples of the present disclosure.

FIG. 15 shows a I-V curve for a solar cell under dark and illuminated conditions according to examples of the present disclosure.

FIG. 16 shows a typical standard solar cell, where the area of optimization is outlined by the dotted region according to examples of the present disclosure.

FIG. 17 shows a plot of power efficiency as a function of filter fraction of the verification model according to examples of the present disclosure.

FIG. 18 shows a plot of silver content as a function of filter fraction of the verification model according to examples of the present disclosure.

FIG. 19 shows a flowchart for a method according to examples of the present disclosure.

FIG. 20 shows a computer system according to examples of the present disclosure.

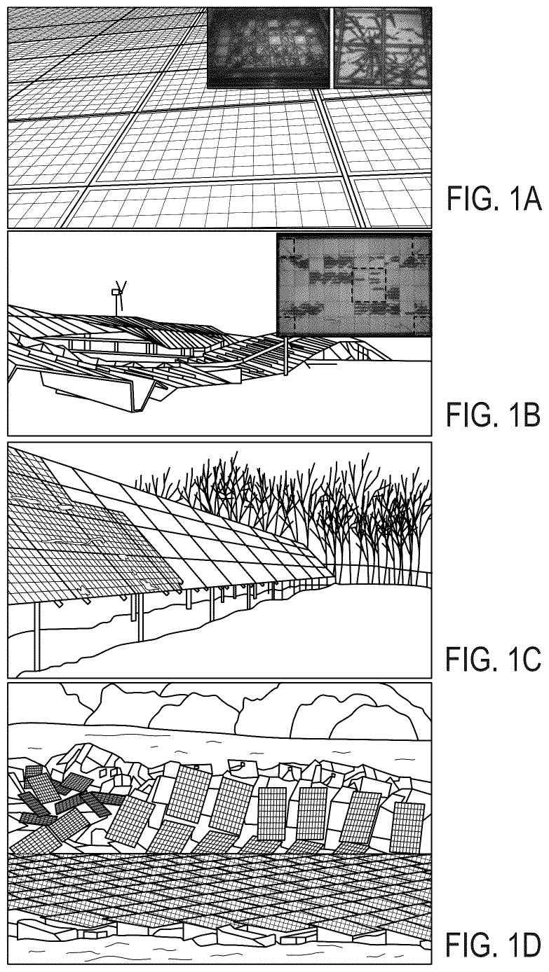

### DETAILED DESCRIPTION

As used herein, a metal matrix composite (MMC), for example, is a composite material that includes multiple components, where additives, such as carbon nanotubes, polymer fibers, and particles, are embedded in and surrounded by metal.

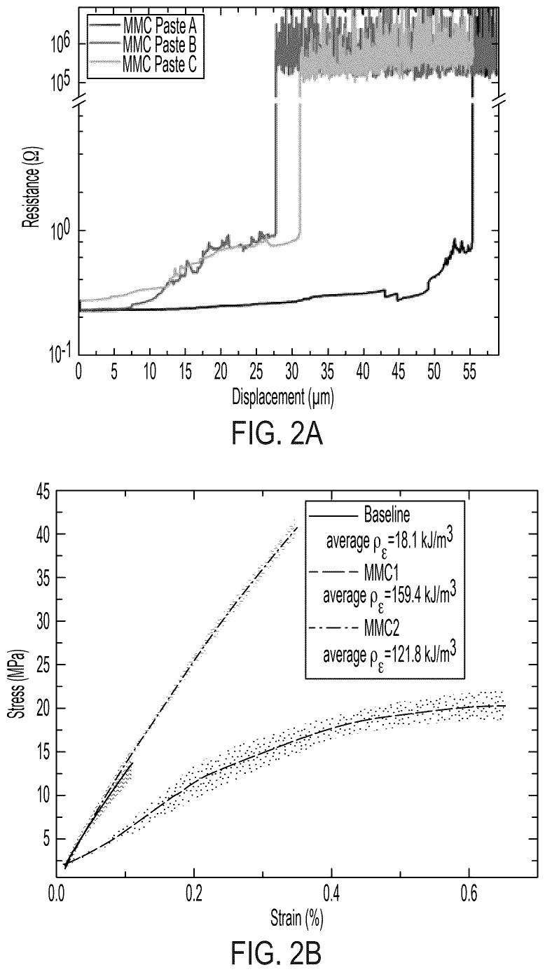

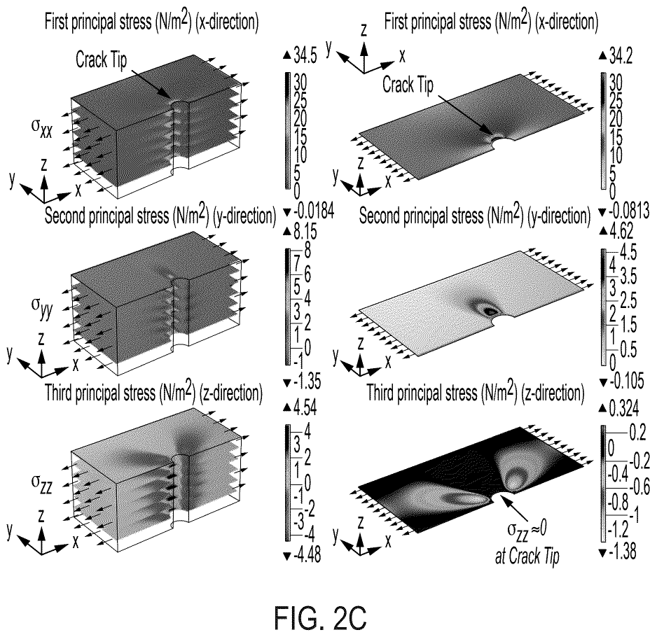

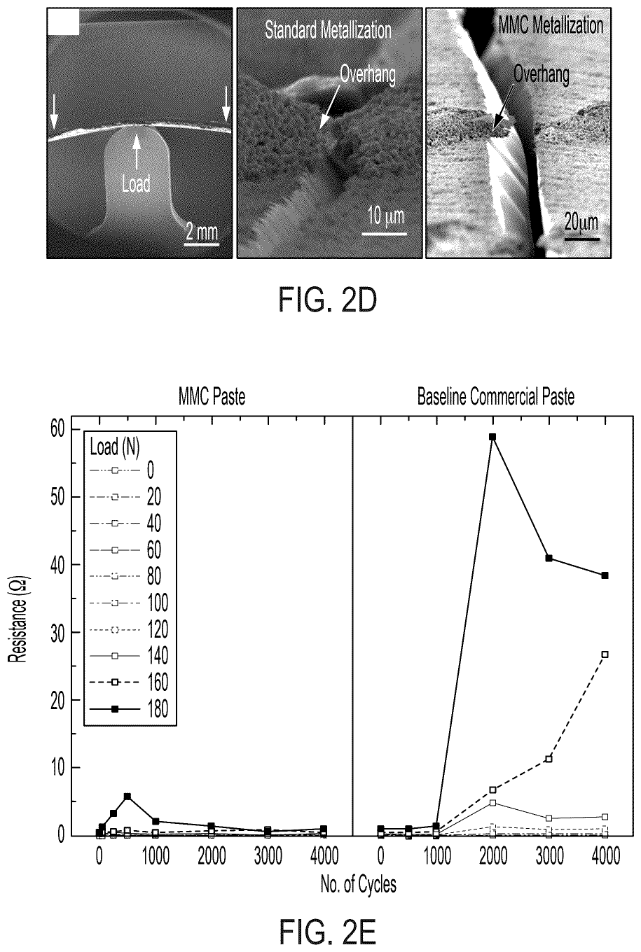

FIG. 2A shows a plot of electrical gap bridging of various MMC pastes; FIG. 2B shows a plot of stress vs. strain curves of commercial base line (-); MMC formulation 1 (- - - ) and MMC formulation 2 (- - - ); FIG. 2C shows principal stress magnitudes at the crack tip; FIG. 2D shows in situ three-point-bending under scanning electron microscope and fractured gridlines over cell cracks; and FIG. 2E shows cyclic mini-module three-point bending test results (courtesy of D2Solar) according to examples of the present disclosure.

PV reliability and lifetime directly impact the effective capacity of US solar electricity generation, virgin material demand, and lifecycle wastes. One of the main module degradation modes that determine PV lifetime is associated with cell cracks. Deceglie et al. recently reported that modules with cracked cells degrade faster than modules without cracked cells. To mitigate cell-crack-induced degradation, a silver metal matrix composite (MMC) metallization for Si PV is disclosed that provides electrical gap-bridging and self-healing properties [see the gap bridging>50 μm in FIG. 2A]. For narrow gridlines and busbars, the triaxiality at the crack tip no longer holds true [see FIG. 2C], and the crack pattern becomes increasingly slanted. The findings suggest that the increased ductility [see - - - stress vs. strain curve of MMC formulation 1 with >0.6% critical strain in FIG. 2B] of MMC metallization further pronounces this ‘slanted’ fracture pattern with elongated ‘overhang’ that electrically bridges the cracks [see FIG. 2D]. FIG. 2E shows that mini-modules constructed from PERC cells with the present MMC metallization withstands over 4000 cycles of three-point-bending at various loads, whereas commercial standard metallization electrically fails after 1000 cycles [see FIG. 2E].

In response to the challenge of cell cracks impacting PV module performance, degradation, and eventual failure, a method to topologically optimize metallization, including metal matrix composite (MMC) metallization, for solar cells to increase their stress and impact tolerance, thus minimizing damage from extreme weather events, are disclosed. The effectiveness of optimized metallization can be evaluated by measuring, for instance, how much reduction in damage (e.g., peak power loss) in PV modules can be achieved with the topologically optimized metallization, including MMC metallization, against standard metallization.

Topological optimization is a structural optimization with multi-physics constraints, in the present case, to improve cell and module efficiency, reduce metal usage, and improve cell and module durability, thus adding value to PV modules while reducing their production costs. What adds further value is through materials engineering of the metal matrix composite formulation. The MMC metallization results in a denser silver microstructure improving conductivity and reducing resistive losses. The effectiveness of optimized metallization design can be evaluated by measuring, for instance, how much reduction in damage (e.g., peak power loss) in PV modules can be achieved with the topologically optimized metallization, including MMC metallization, against standard metallization designs. Topological optimization entails designing gridlines and busbars for (1) maximum current collection (thus maximum cell efficiency), (2) decreased silver usage, (3) tolerance for stress observed in fielded modules, and (4) resilience to cell cracks and crack patterns that reflect specific weather events (wind/snow load vs. hail impact). This is done while maintaining the same or less metal coverage on the cell surface to maximize the sunlight capture, keeping the gridline dimensions above the minimum screen-printable features, and considering manufacturability (e.g., cell-to-cell ribbon soldering). The disclosed optimization approach addresses the realistic constraints of manufacturing, de-risking the complexity and difficulty of introducing a new design solution to the market.

The disclosed topological optimization also builds on capability of enhancing electromechanical properties of silver paste. A method to embed low-cost, carbon-nanotubes (CNTs) within metal contacts can be used. CNTs are incorporated into commercial silver (Ag) pastes, which can be screen-printed and fired. The CNT-enhanced pastes are designed as a plug-and-produce solution within a preestablished manufacturing process flow. The screen-printing and firing schedules are virtually identical to industry standard procedures without compromising contact and line resistance and ultimately beginning-of-life cell performance. The CNTs serve as electromechanical reinforcement that preserves the cell performance in the presence of cracked substrates and fractured metal contacts. As discussed herein, CNT-metal composites are referred to as metal matrix composites (MMCs).

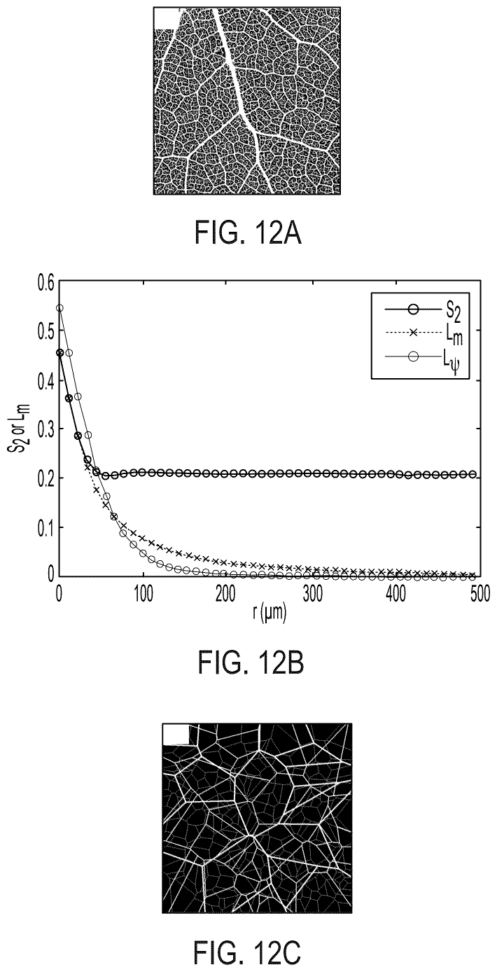

FIG. 12A demonstrates one way to optimize the metallization, borrowing the inspiration from leaf vein, according to examples of the present disclosure. The leaf vein is nature's optimized structure for delivering nutrients and water for plants, and one can mimic the structure to maximize the current delivery in solar cells. In the present case, mathematical descriptors, such as auto-correlation and lineal path function [FIG. 12B] are used to produce fabricated structures that share the same or similar descriptors. While the descriptors might be identical, these fabricated structures may not necessarily look the same visually. One can also utilize overlapping Voronoi patterns [FIG. 12C] observed in nature to maximize the current delivery in PV cells.

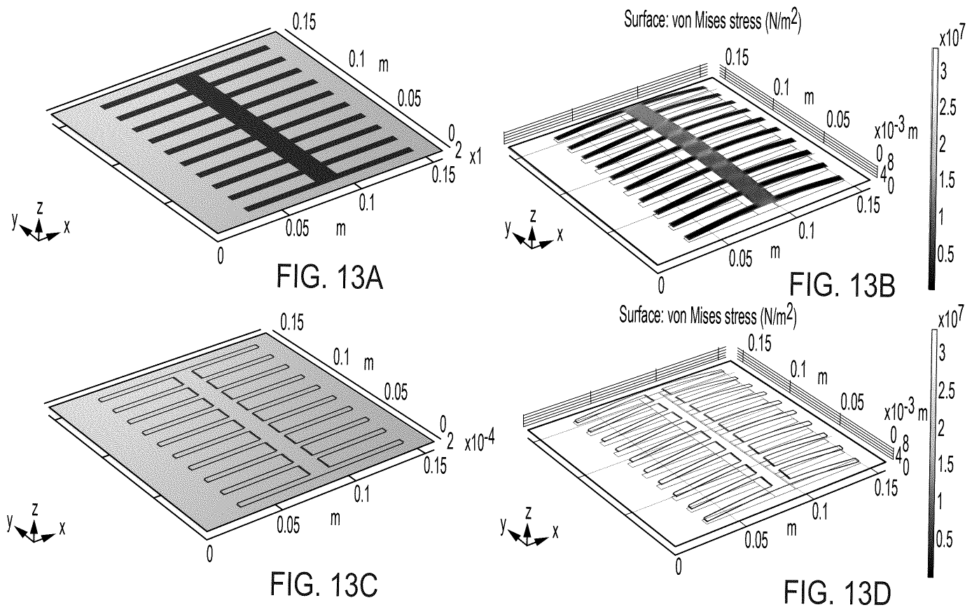

FIG. 13A shows a “Unit cell” of conventional busbar and gridlines, FIG. 13B shows a conventional metallization under stress, FIG. 13C shows a topologically optimized metallization design against stress according to examples of the present disclosure, and FIG. 13D shows reduced stress in topologically optimized metallization according to examples of the present disclosure. Adding to the two optimization approaches described above, FIG. 13A, FIG. 13B, FIG. 13C, and FIG. 13D provide an example of topological optimization approach with manufacturing constraints discussed above. The stress is minimized within the gridlines and busbars, by allowing the gridline and busbar structures to morph, particularly by shedding mass in the interior of both structures.

The particular set of constraints applied here include (1) holding the original outer perimeter of the gridlines and busbars intact and (2) applying relatively high stress (2400 Pa) to deflect the gridlines and busbars. The example is provided only for the purpose of demonstrating the concept of topological optimization. One can apply manufacturing-relevant constraints to optimize the metallization design for current collection, stress reduction, and crack formation as well as crack patterns.

Complementing the disclosed topological design optimization, MMC metallization, which includes commercial silver paste and low-cost carbon nanotubes, provides substantially increased fracture toughness. Since the initial demonstration of enhanced electromechanical properties, continuous improvement of the composite formulation has achieved (1) an increase in fracture toughness compared to standard metallization by >6 fold, (2) ability to electrically bridge gaps >50 μm in cracked cells, and (3) self-healing of gridlines regaining electrical continuity after eventual electrical failure of metallization under extreme strain. The composite metallization, as a plug-in solution, does not require any changes to the existing manufacturing process.

In addition to the immediate benefit of reliable power generation, the topologically optimized gridlines increase cell efficiency, while reducing silver usage. The use of CNTs in composite paste enhances silver particle sintering under identical firing conditions to standard baseline silver paste, thus providing increased conductivity and reduced resistive losses. Combined, these advantages help further reduce the manufacturing cost of PV modules and thus reduce the levelized cost of energy for the public. The reduction in silver usage would prove especially significant in consideration of the projected shortage of global silver supply by 2030 to meet the PV production demand and the DOE goal to reach complete decarbonization of the electricity sector by 2035.

According to examples of the present disclosure, the topological design optimization of gridlines is disclosed and evaluated as to whether the approach can further improve module resilience to cell-crack induced degradation, while improving efficiency and reducing silver usage by comparing standard vs. topologically optimized gridline designs, using a commercial paste, and by comparing the same comparison on gridline designs, using the MMC paste. The following features are considered.

Achieve beginning-of-life performance [e.g., η, FF, J_{sc}, V_{oc}, Rₛ, Rₛₕ, etc.] of bifacial p-type Passivated Emitter and Rear Contact (p-PERC) cells with topologically optimized gridline design to be comparable or better than standard gridline design. This can be met with both commercial silver paste and MMC paste. The baseline for comparison is commercial silver paste metallization with standard gridline design with 5 busbars.

Improve current collection and therefore improve cell efficiency by topologically optimizing the gridline design, while using comparable or less silver than the conventional gridline design. For example, up to 10% less silver usage for the comparable cell performance (η~21 to 22%) is provided, while offering substantially improved fracture tolerance.

Topologically optimize the gridline design to achieve less stress and less fracture from extreme weather events (e.g., wind/snow load and hailstone impact). Demonstrate reduced degradation through accelerated testing (e.g., less than 30% degradation in power generation after hail impact test as commonly observed for standard modules).

Achieve manufacturability comparable to standard cell production (i.e., no added manufacturing steps, compatible with standard screen-printing processes, compatible with standard firing profiles, and compatible with standard ribbon soldering processes).

Materials Engineering to Withstand Module Stress and Deflection during Severe Weather

The first approach is to make the gridlines and busbars intrinsically stronger than what was possible with conventional metallization. To that end, low-cost, surface-functionalized, carbon nanotubes (CNTs) can be incorporated into commercial silver paste to form metal matrix composites (MMCs). Using MMCs, the composite gridlines exhibit substantially enhanced fracture toughness, electrical gap-bridging of cracked solar cells, and “self-healing” to regain electrical continuity after many cycles of strain-induced failure. The beginning-of-life solar cell performance from composite metallization also matches that of conventional metallization. For this effort, the mechanical strength and fracture toughness of the MMC is enhanced to withstand the levels of mechanical stress that the gridlines and busbars would experience during extreme weather conditions.

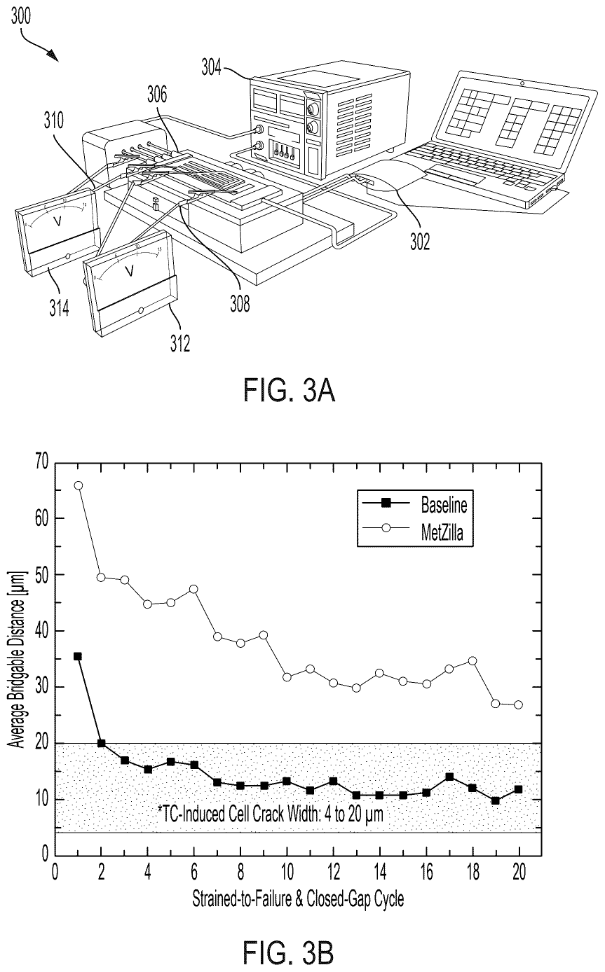

FIG. 3A shows a RACK setup 300 to measure electrically bridgeable gap in cell cracks and to monitor “self-healing” according to examples of the present disclosure. The RACK setup 300 can comprise a data acquisition (DAQ) system 302, a direct current (DC) power supply 304, power reserve 306, such as a 20 W power reserve, a piezoelectric stage 308, a voltage drop power reserve 310, and two voltage drop samples 312, 314. FIG. 3B shows strain-induced failure and self-healing cycles for MetZilla MMC metallization level off at ~30 μm compared to ~10 μm for standard “baseline” metallization according to examples of the present disclosure.

Even with the superior mechanical strength, MMC gridlines would eventually fail against the stress caused by Category 4 and Category 5 hurricane winds. However, MMC gridlines can “self-heal” after multiple cycles of strain-induced mechanical failure. FIG. 3B shows that MMC gridlines can electrically bridge ~65-μm-wide cell cracks. The electrically bridgeable gap in the cell crack can be measured by a Resistance Across Cleaves and cracks (RACK) setup [see FIG. 3A], where the gridlines are printed and fired on a silicon substrate, and the substrate is cleaved in half and pulled apart until the gridlines on top of the substrate electrically fail. The electrical resistance along each gridline is measured, and the resistance rises to infinity when the gridline electrically fails.

The MMC gridlines electrically fail as the cell crack width opens up >65 μm at first, but regain their electrical continuity as the cell crack width narrows to 50 μm. Then, the MMC gridlines are strained again to failure, but they regain electrical continuity, when the cell crack width narrows to 49 μm. This process can be repeated, and the “self-healable” gap levels off at ~30 μm. In comparison, the standard baseline metallization can initially bridge 35 μm gap and levels off at ~10 μm. A similar behavior is observed from other standard commercial gridlines, where the bridgeable gap decays from 15 μm to ~10 μm. Silverman et al. have shown that cell crack width ranges from 4 to 20 μm in a module, opened up through thermal cycling (TC), and that these cracks can lead to electrical discontinuity. Assuming that this crack width range is typical of cell cracks, after wind load is taken off, the MMC gridlines are expected to self-heal and regain electrically continuity, whereas the standard baseline gridlines may not.

### Topological Optimization for Current Collection and Minimal Stress

The mathematical foundation for structural topological optimization has been well established. To illustrate, Gupta et al. have applied the approach to optimizing metallization patterns for solar cells. While the metallization patterns from Gupta's work are not screen printable or manufacturable, his work showed the potential of topological optimization. In this disclosure, a topological optimization is applied to improve the gridline design for maximum cell efficiency, minimum stress, and minimum damage from high impact events. The outcome from computational optimization strongly depends on the accuracy of governing device physics and physical parameters (e.g., current density representing minority carrier generation rate; minority carrier recombination rate; single diode parameters, such as series and shunt resistance; conductance in emitter; etc.). Using inaccurate physics and unrealistic physical parameters can lead to an outcome that would neither provide the desired improvement nor match the experimental result. While accounting for accurate material and device parameters that are representative of experimentally measured values, realistic constraints are placed on the optimization: (1) maintain the same or less metal coverage on the cell surface to maximize the sunlight capture, (2) keep the gridline dimensions above the minimum screen-printable features, and (3) keep the conventional busbar design in consideration of manufacturability (e.g., cell-to-cell ribbon soldering).

The physics model describes the generation of electrical power by an illuminated solar cell. When the silicon region is illuminated, it should generate power, while the metallic silver region transfers power out of the cell, but the silicon underneath it does consume some power. The total power generated is the total power summed over the whole unit cell. Any transient effects are ignored, and it is assumed that the solar cell is operating at steady-state, uniform illumination conditions. The solar cell experimental data was obtained under standard 1 sun conditions equal to 100 mW/cm².

To handle DC current sources, the continuity equation and Ohm's law are combined to give:

$$- ∇ \cdot ( σ ∇ V - {J}_{e} ) = {Q}_{j} \qquad 1$$

where Vis the electrical potential (SI unit: V), Jₑ is the externally generated current density (Si unit: A/m²), σ is the electrical conductivity (SI unit: S/m), and Qⱼ is the current generation. Qⱼ describes the current density generated by the solar cell. For planar 2d cases, where the electrical potential varies only in the x and y directions, equation 1 becomes, where d_{z} is the thickness in the z direction:

$$- ∇ \cdot ( σ ∇ V - {J}_{e} ) = {d}_{z} {Q}_{j} \qquad 2$$

Electrical power density is calculated by: P(x, y)=J(x,y) V(x, y).

The single diode model is simple model used to describe the behavior of a solar cell. The single diode current density model is:

$$J = {J}_{L} - {J}_{D} - {J}_{s h} \qquad 3$$

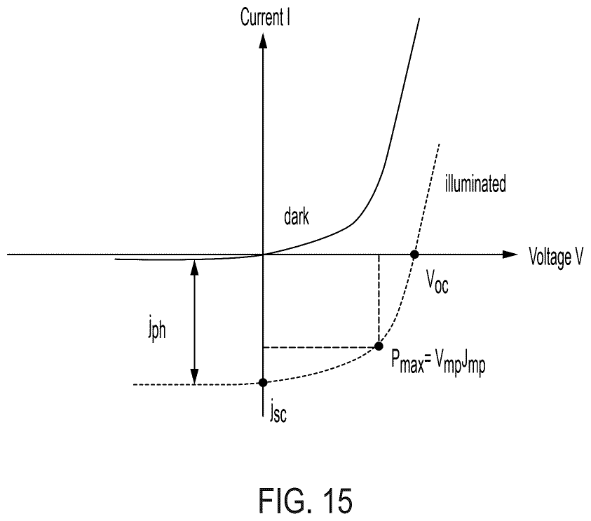

The current density, J, within a single diode is a function of the light-generated current density, J_{L}, the voltage dependent recommendation current density or dark current density, J_{D}, and the lost shunt current density, Jₛₕ. Equation 3 is a non-separable equation since both J_{D} and Jₛₕ are functions of J. J can be obtained by iterative methods or by software such as SPICE, but it is impractical for optimization techniques. J can also be described by the transcendental Lambert W function, which allows for differentiation, but difficult to implement. In an ideal situation, the p-n junction illuminated by a light source would be modelled. However, this approach requires expensive multiscale modelling. Alternatively, experimental data or curve fitting of data is used. FIG. 15 shows an I-V curve for a solar cell under dark and illuminated conditions according to examples of the present disclosure. Under the dark condition, when the solar cell is not illuminated by light, it should be in quadrant I consuming power. As the voltage is decreased, it should intercept the origin and go into quadrant III where it consumes power. When the solar cell is illuminated, the I-V curve will shift down into quadrant IV where power is generated. The curve should NEVER enter quadrant II. A curve in quadrant II, implies that electrical energy is flowing out of the solar cell while releasing solar energy and generating power. To avoid this situation, the I-V curve should never be in quadrant II, and any data or equation fits should be checked to make sure they are not in quadrant II.

The light-generated current density, J_{L}, is a function of the ability of the solar cell to convert solar energy into electrical energy G_{Light} and the solar power density Pₛₒₗₐᵣ which gives:

$${J}_{L} = {G}_{Light} {P}_{S o l a r} \qquad 4$$

Therefore, only an equation fit of the dark current density is required. To avoid any artifacts, as V→∞, J must also go to co. Additionally, V→∞, J→−∞, to avoid any nonphysical results and make sure the voltage remains in a realistic range of ∓0.5 V. The remaining terms of equation 3 are equal to the dark current density such that:

$${J}_{d a r k} = - {J}_{D} - {J}_{s h} \qquad 5$$

Experimental data is used in tabular form or an equation fit to describe/dark.

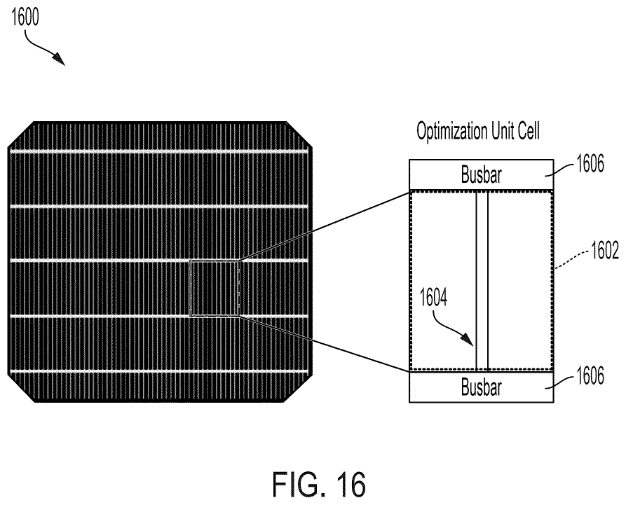

FIG. 16 shows a solar cell 1600 with the area to be optimized outlined by the dotted region 1602. The solar cell comprises of a silicon substrate with silver metallization. The silver metallization comprises fingers 1604, that collect current that is generated within the silicon region and busbars 1606 which collect current from the fingers 1604 and transfers it to other solar cells and an inverter. To reduce complexity, a characteristic unit cell of a solar cell is used. Table 1 shows the dimensions used to generate the Optimization Unit Cell. For the simulation, only half of the busbar is used for the top and bottom. Periodic boundary conditions are used for the top/bottom and left/right.

TABLE 1
Dimensions of the solar unit cell

| Dimension | Value | Unit |
|---|---|---|
| Silicon Width | 5 | mm |
| Silicon Height | 30.63 | mm |
| Busbar Width | 5 | mm |
| Half Busbar Height | 88.9 | μm |
| Finger Width | 50.8 | μm |
| Finger Height | 30.63 | mm |
| Silicon Depth | 1 | μm |
| Silver Depth | 50 | μm |

TABLE 2
contains the pure material properties and solar cell performance
electrical properties used in the initial optimization.

| Material and Electrical Properties | Value | Unit |
|---|---|---|
| Silicon Relative Permittivity, ε_{Si} | 11.7 | — |
| Ag Relative Permittivity, ε_{Ag} | 1 | — |
| Ag Conductivity, σ_{Ag} | 6.16E+07 | S/m |
| Silicon Conductivity (doped), σ_{Si} | 10000 | S/m |
| Solar Illumination Power, P_{Solar} | 1000 | W/m² |
| Input Voltage, V_{bus} | 0.56264 | V |
| G_{Light} | −0.40914 | A/W |

The optimization objective function is to maximize the power generated by the solar unit cell. For a diode power is generated in quadrant IV, so the goal is to minimize the electrical power. Additionally, the silver content should be minimized. Solid Isotropic Material with Penalization method (SIMP) is used to describe the density distribution of material, θ, within the system. θ=1 is where the material was only silver, while θ=0 was used for pure silicon. Alloy is used to describe the non-pure material. The SIMP exponent used for interpolation and optimization was P_{SIMP}=3.

### Relative Permittivity Interpolation:

$${ε}_{A l l o y} = ( {ε}_{A g} - {ε}_{S i} ) {( {θ}_{A l l o y} )}^{{ρ}_{SIMP}} + {ε}_{S i} \qquad 4$$

### Conductivity Interpolation:

$${σ}_{A l l o y} = ( {σ}_{A g} - {σ}_{S i} ) {( {θ}_{A l l o y} )}^{{ρ}_{SIMP}} + {σ}_{S i} \qquad 5$$

### Out-of-Plane Thickness Interpolation:

$${d}_{A l l o y} = ( {d}_{A g} - {d}_{S i} ) {( {θ}_{A l l o y} )}^{{ρ}_{SIMP}} + {d}_{S i} \qquad 6$$

### Power Illumination:

$${P}_{A l l o y} = {{P}_{S o l a r} ( 1 - {θ}_{A l l o y} )}^{{ρ}_{SIMP}} \qquad 7$$

Silver is not transparent to light therefore no solar power is collected.

### Silicon Light Current (A/m³):

$$J = ( {G}_{Light} {P}_{S o l a r} + {J}_{d a r k} ( V ) ) / {d}_{S i} \qquad 8$$

### Silver Dark Current (A/m³):

$$J = {J}_{d a r k} ( V ) / ( {d}_{S i} + {d}_{A g} ) \qquad 9$$

### Alloy Light Current (A/m³):

$$J = ( {G}_{Light} {P}_{A l l o y} + {J}_{d a r k} ( V ) ) / {d}_{A l l o y} \qquad 10$$

### Silver Volume (m³):

$${V}_{A g} = \int \int {d}_{A l l o y} ( x , y ) dxdy \qquad 11$$

### Local Collected Power Surface Density (W/m²):

$${P}_{S D} ( x , y ) = V ( x , y ) J ( x , y ) {d}_{A l l o y} ( x , y ) \qquad 12$$

### Total Collected Power (W):

$${P}_{Total} = \int \int {P}_{S D} ( x , y ) dxdy \qquad 13$$

To have a valid dark current fit, the dark current must only cross the x-axis at the origin. A standard polynomial fit fails due to the oscillations do cross the x-axis providing unrealistic behavior. A piecewise equation is used instead. The PERC solar cell performance was measured down to −0.22 V, while a function was added to model reverse voltage breakdown which causes hotspots and failure of the solar cell.

$${J}_{d a r k} ( V ) = \{ \begin{matrix}a + bexp ( c V ) , & if ( V > 0 ) \\ 0 , & if V == 0 \\ {m}_{1} V + {b}_{1} , if & - 0.22 \leq V < 0 \\ {m}_{2} V + {b}_{2} , & if V < - 0.22\end{matrix} \qquad 14$$

The parameters used in this piecewise function are listed in Table 3.

TABLE 3
Parameters for J_{dark} piecewise function

| | |
|---|---|
| a | 0 |
| b | 1.27E−06 |
| c | 25.94253 |
| m₁ | 0.38886 |
| b₁ | 0 |
| m₂ | 30 |
| b₂ | 6.520373 |

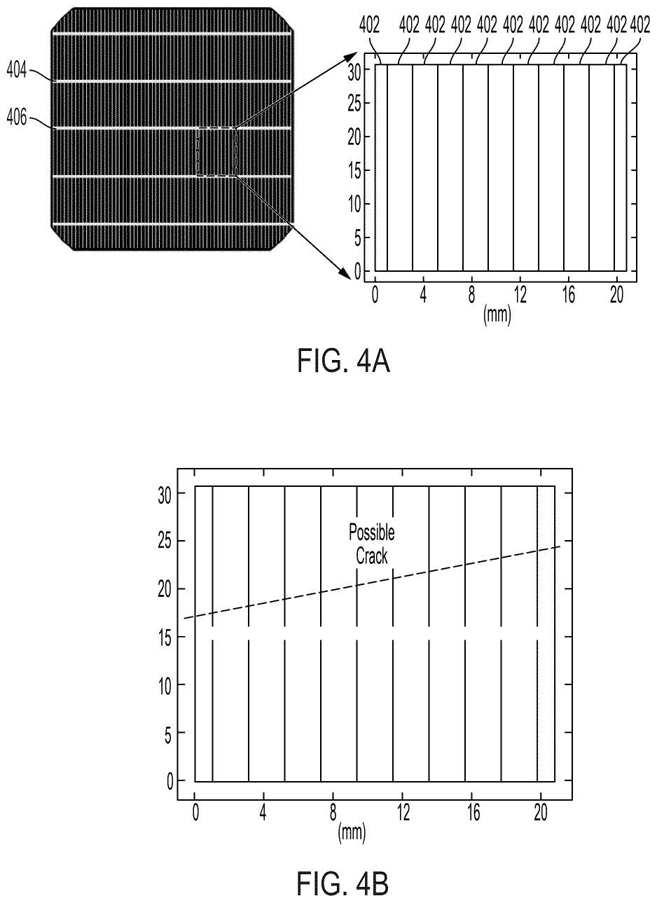

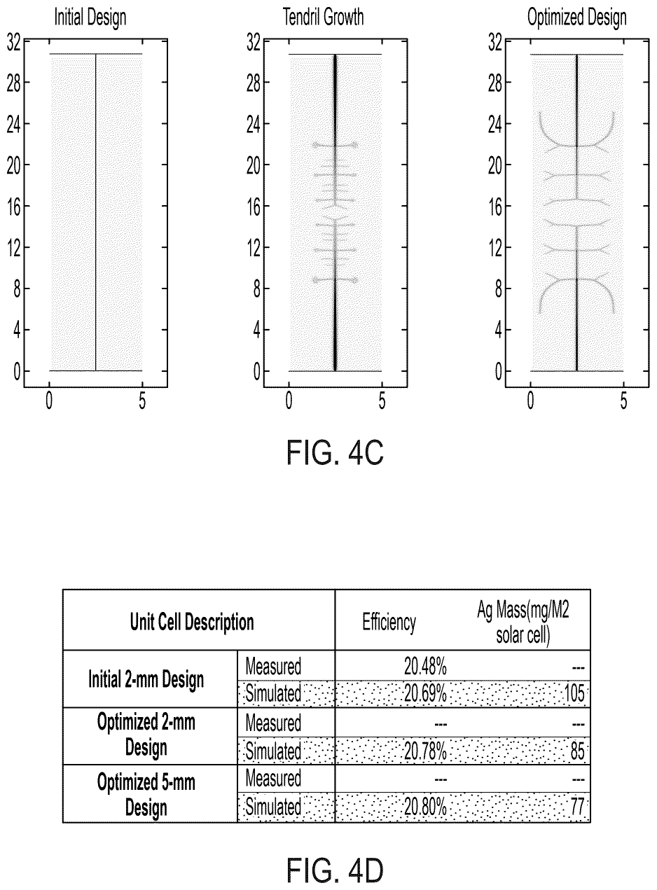

After the optimization converges, the results are used to construct a verification model. The values of θ range from 0 to 1. A filter fraction, Γ, is selected to determine the cutoff point between silver and silicon. These filtered results are used to construct the verification model. Different values of Γ are used to maximize power while minimizing silver content. FIGS. 3 and 4 show the power efficiency (simulated power density/Solar Illumination Power) and silver content as a function of Γ. In the case for these results, the power efficiency peaked at Γ=0.39, while the silver content kept decreasing.

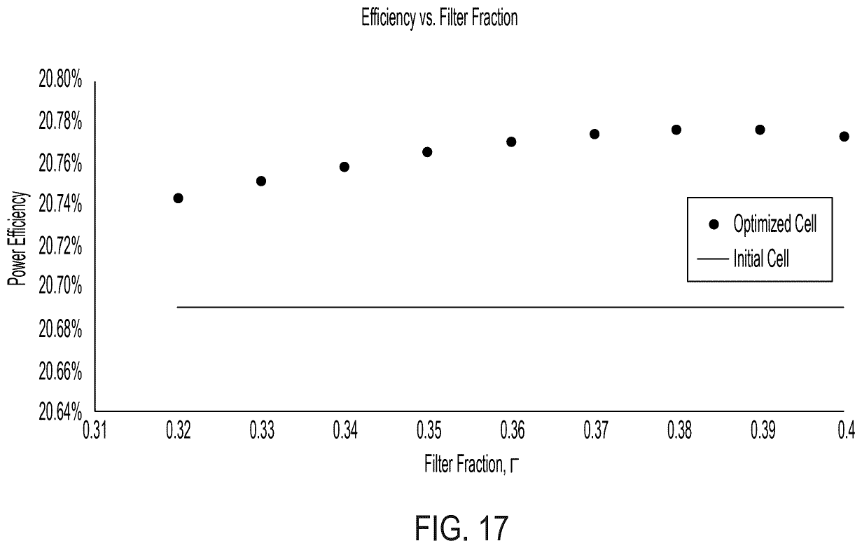

FIG. 17 shows a plot of power efficiency as a function of filter fraction of the verification model.

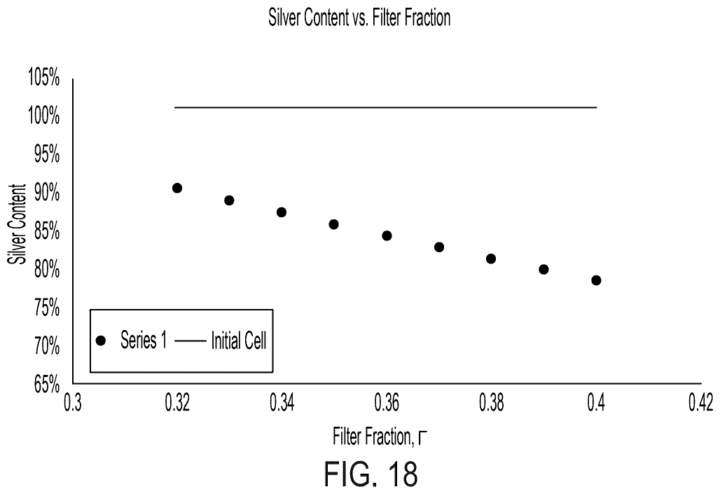

FIG. 18 shows a plot of silver content as a function of filter fraction of the verification model.

The photocurrent densities (j_{L}) and dark densities (j_{D}) are extracted from experimental measurements of a reference PERC cell as a function of voltage. The reference cell photocurrent is measured under 1000 W/m² of sunlight intensity at standard conditions (1.5 Air Mass). The simulated solar cell performance is confirmed to closely match the experimental cell performance [see the matching numbers for efficiency and Ag laydown weight from the standard 2-mm-pitch gridline design in FIG. 4D; 20.48% vs. 20.69% and 112 mg/wafer vs. 105 mg/wafer].

Solid Isotropic Material with Penalization (SIMP) density model is coupled with the gradient-based Method of Moving Asymptotes (MMA) solver to optimize the gridline structure for improved solar cell performance and reduced silver usage. The solver maximizes the solar power generated by spatially manipulating the silver volume fraction, 1, which varies between 0 (pure silicon) and 1 (pure silver) to form an optimized silver-silicon alloy structure.

Relevant material and structural parameters, such as electrical conductivity, relative permittivity, and material thickness variability. An adaptive mesh compliments the developing gridline structure, which reduces the required computation time and guarantees mesh-independent results. The converged solution provides position-dependent 1 values over the optimized area; however, a silicon-silver alloy is not physical or relevant. Thus, a step-function filter is used to extract discrete silver and silicon domains as a binary choice. The optimized gridline structure is then used in simulation to extract cell performance, which outperforms the simulated reference cell performance, while simultaneously reducing silver usage [see efficiency and Ag laydown weight for optimized 2-mm gridline pitch and 5-mm gridline pitch results in FIG. 4D]. For the disclosed work, the topologically optimized design is screen printed and fired on p-type bifacial PERCs and experimentally validate the enhanced gridline structure.

FIG. 4A, FIG. 4B, FIG. 4C, and FIG. 4D shows one example of an optimized design, using a subsection of a cell with 10 gridlines 402 between two busbars 404, 406 according to examples of the present disclosure. Only gridlines are shown in the right-hand-side diagram of FIG. 4A, bordered by two horizontal busbars at top and bottom. In consideration of manufacturability, the busbars are left intact, and the location where the gridline connects with the busbar is fixed at a constant pitch (2 mm or 5 mm). FIG. 4A and FIG. 4B are not drawn to scale where the x-axis is stretched compared to y-axis to make the gridlines more visible. In FIG. 4C, dark fingers represent silver gridlines, and lighter regions represent the underlying silicon emitter.

The result from this initial optimization is that as much as 27% less silver can be used, while increasing the cell efficiency by 0.11%. The result shows improved cell efficiency, while reducing the surface coverage of silver. A few features are noted in this outcome. (1) Gridlines are separated in the middle between two busbars for 2-mm-pitch design, thus leading to less silver usage [see FIG. 4C]. Depending on the additional loss mechanisms of minority carriers (so far captured by Rₛₕ), loss terms may have to be explicitly added to Eqn. (1), and this gap in the middle that saves silver may have to be narrowed. The gridline separation in the middle can also lead to undesired losses in the event of cell cracks. For instance, cell cracks propagating laterally or diagonally [example shown by dotted line in FIG. 4B] and severing gridlines can render the gridlines below the crack unable to collect current. This example illustrates that other considerations must be made to the design options optimized for efficiency. A gridline pattern is considered where the top row of gridlines and bottom row of gridlines are staggered to varying degrees (like inter-digitated combs) as initial condition and determine whether such staggering would improve efficiency. (2) As the gridline pitch increases from 2 mm to 5 mm, the silver tendrils branch out laterally to collect charge carriers [see FIG. 4C], an organic growth often observed in topological optimization. The 5-mm-pitch case clearly demonstrates the possible level of reduction in silver usage (~27%).

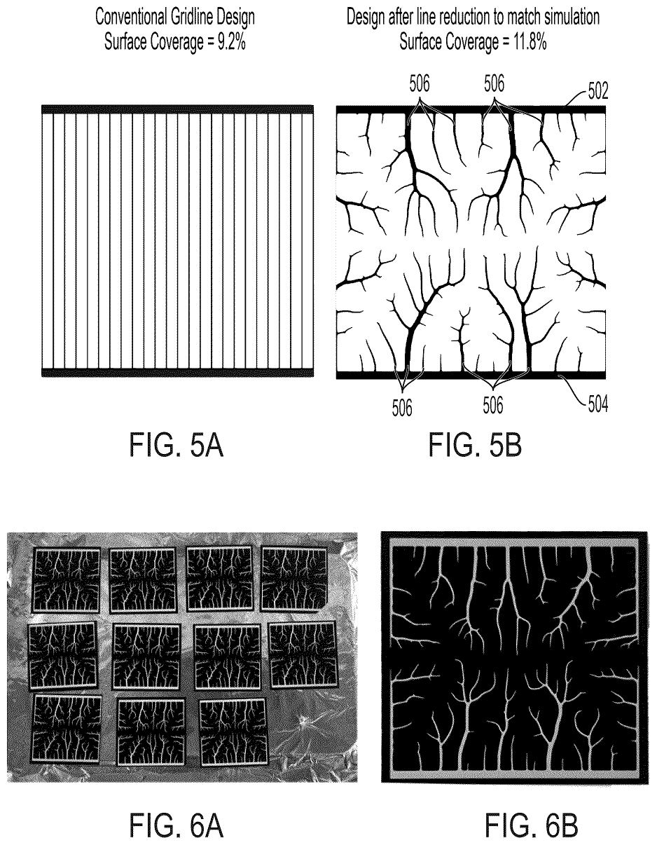

FIG. 5A and FIG. 5B show the outcome of a topological optimization according to examples of the present disclosure, where the initial condition (i.e., initial structure) is standard rectangular gridlines, essentially capturing the main feature of current optimized structure in FIG. 4A, FIG. 4B, FIG. 4C, and FIG. 4D.

Minimum Stress: For topological optimization to minimize the structural stress, subjected to a deflection, and to visualize the stress profile, the following governing equations are used. For determining the von Mises stress of the solar cell, the tensor version of the steady state equation of motion is used: ∇·σ+F=ρü. The strain tensor is described by:

$$ε = \frac{1}{2} [ ∇ u + {( ∇ u )}^{T} ] .$$

Silicon and silver are assumed to be isotropic linear elastic materials, where Hooke's law is used to couple the material behavior to stresses and strains: σ=C:ε. For the equations above, σ is the Cauchy stress tensor, ε is the strain tensor, Cis the stiffness tensor which is a function of Young's modulus and Poisson's ratio, Fis the body force, and ρ is the mass density of the material. For the stress optimization, the von Mises stress is minimized while reducing the total volume of silver material.

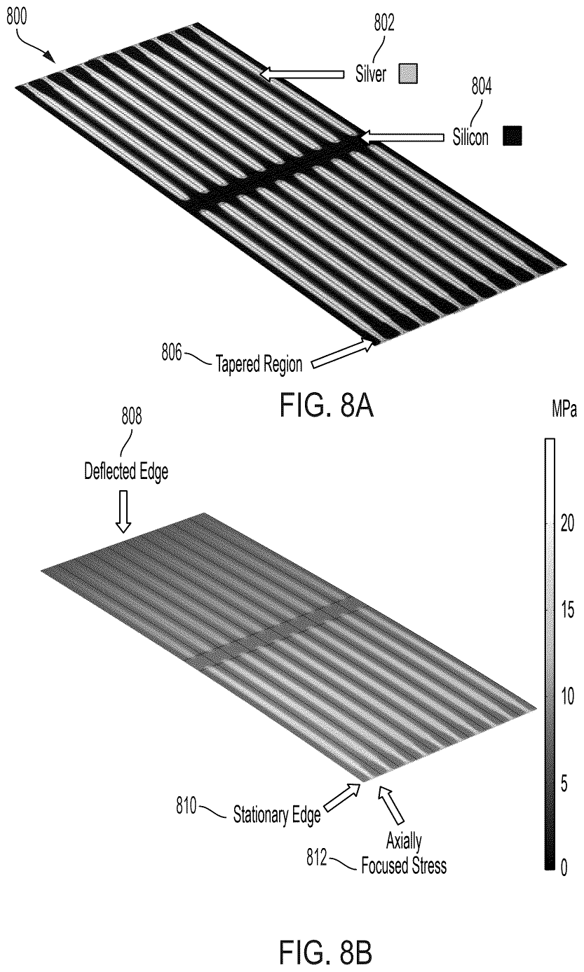

FIG. 8A shows gridline design topologically optimized to minimize stress, when subjected to a deflection corresponding to 2400 Pa front load according to examples of the present disclosure. As shown in FIG. 8A, solar cell 800 comprises underlying silicon emitter 804 with silver topologically optimized gridlines 802 that taper to a taper region 806 near an edge of solar cell 800. FIG. 8B shows a stress profile within the gridlines according to examples of the present disclosure. As shown in FIG. 8B, the stress profile of solar cell 800 shows deflected edge 808, stationary edge 810, and axially focused stress 812.

To simulate the substrate deflection under 2400 Pa load [FIG. 8A and FIG. 8B], one busbar edge, for example busbar 810, is held stationary, while lowering the opposite busbar edge, for example busbar 800, [see FIG. 8B]. This is only an estimate since the location of the node and neutral axis in a real module and cells would be different. A few features are noted. (1) The optimized gridlines 802 taper down near and towards the busbars but flare out as they meet the busbars, much like the neck in an hourglass. The hourglass feature, while minimizing the stress in large part of the gridlines, is counter to the current optimization, where the gridlines become wider as they approach the busbars. This calls for iterative optimization and modification in the gridline design near the busbars to meet both current collection and stress minimization goals. (2) While the maximum stress remains at ~25 MP, the stress is axially focused along the gridlines, gradually increasing towards the busbar on the stationary edge. This contrasts with standard gridlines, where the maximum stress is shown near the stationary edge, but it is evenly distributed within the gridlines. That is, the maximum stress region occupies less volume with the topological optimized gridlines.

### Monte Carlo Simulations and Testing for Hail Impact Damage

Due to stochastic nature of cell cracks upon high impact events, optimizing the gridline design against hail damage is an enormously difficult challenge and carries the highest risk in the engineering effort. As a first step towards addressing this challenge, Monte Carlo (MC) simulations of hail impact events are conducted to select the best topologically optimized design.

FIG. 6A and FIG. 6B show a small 2-inch×2-inch PERC cells screen-printed with topologically optimized gridline design according to examples of the present disclosure.

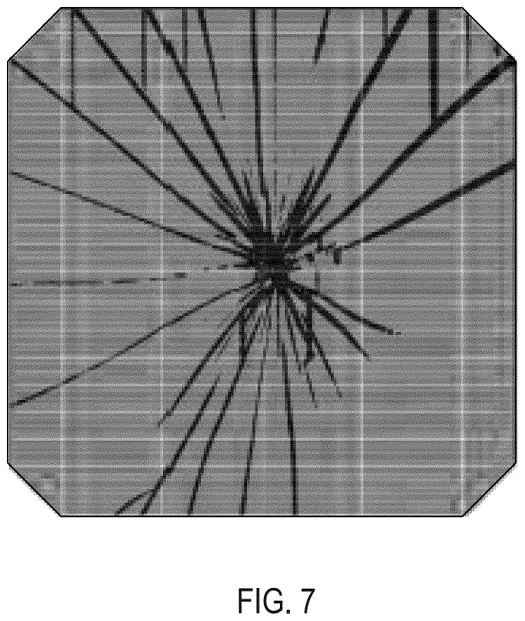

FIG. 7 shows a schematic of hailstone impact on a solar cell with 5-busbar gridline design.

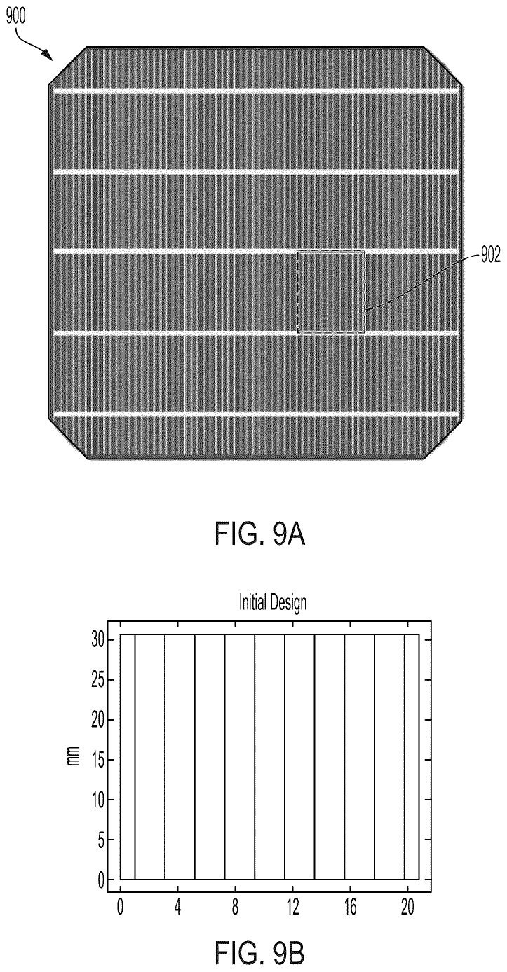

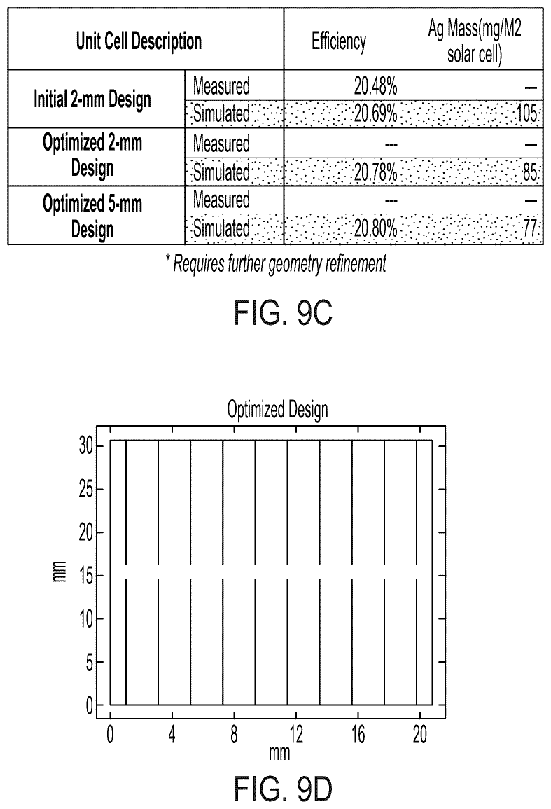

FIG. 9A, FIG. 9B, FIG. 9C, and FIG. 9D shows examples of solar cell designs according to examples of the present disclosure. As shown, FIG. 9A shows a solar cell 900 with highlighted portion 902, for example the unit cell, which is shown in detail in FIG. 9B. FIG. 9B shows 10 topologically optimized busbars. FIG. 9C shows a table of unit cell descriptions. FIG. 9D shows another 10 topologically optimized busbars.

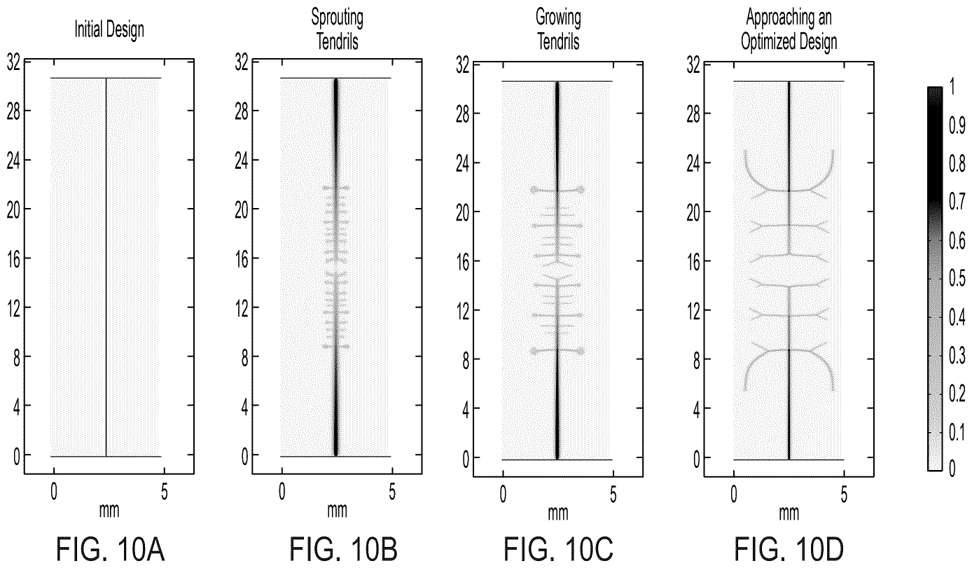

FIG. 10A, FIG. 10B, FIG. 10C, and FIG. 10D shows time-series progression of topological optimization of a single gridline set between two busbars (i.e., snapshots through time how the topological optimization evolves) according to examples of the present disclosure.

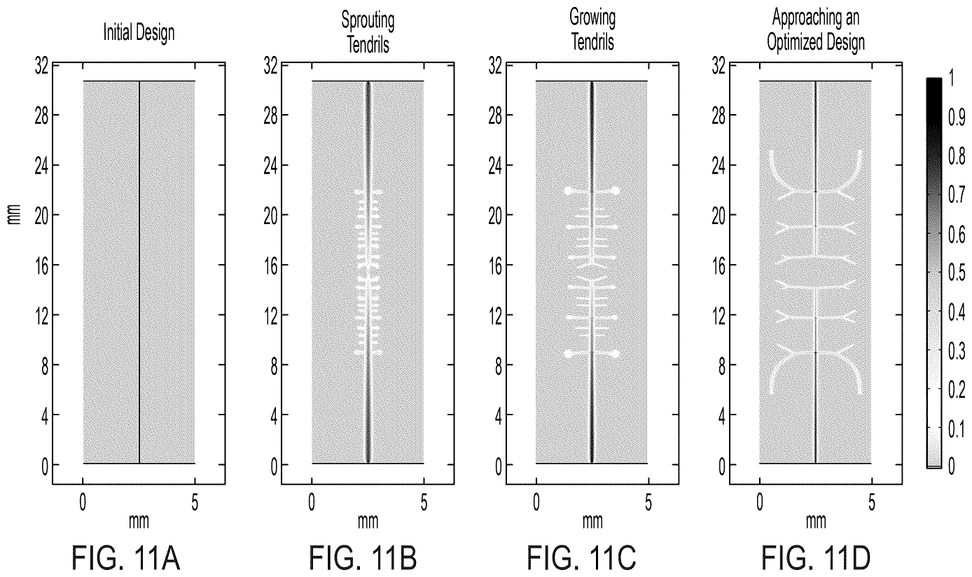

FIG. 11A, FIG. 11B, FIG. 11C, and FIG. 11D shows example dimensional plots for an optimized gridline design according to examples of the present disclosure.

FIG. 12A shows a 7065 μm×7065 μm digitized image of a leaf vein pattern according to examples of the present disclosure. FIG. 12B shows an auto-correlation and a lineal path function extracted from the image according to examples of the present disclosure. FIG. 12C shows three overlapping Voronoi patterns of different line widths according to examples of the present disclosure. FIG. 12A demonstrates one way to optimize the metallization, borrowing the inspiration from leaf vein. The leaf vein is nature's optimized structure for delivering nutrients and water for plants, and one can mimic the structure to maximize the current delivery in solar cells. In this case, mathematical descriptors, such as auto-correlation and lineal path function [FIG. 12B], are used that produce fabricated structures that share the same or similar descriptors. While the descriptors might be identical, these fabricated structures may not necessarily look the same visually. One can also utilize overlapping Voronoi patterns [FIG. 12C] observed in nature to maximize the current delivery in PV cells.

FIG. 13A shows a “Unit cell” of conventional busbar and gridlines. FIG. 13B shows a conventional metallization under stress. FIG. 13C shows a topologically optimized metallization design against stress. FIG. 13D shows a reduced stress in topologically optimized metallization.

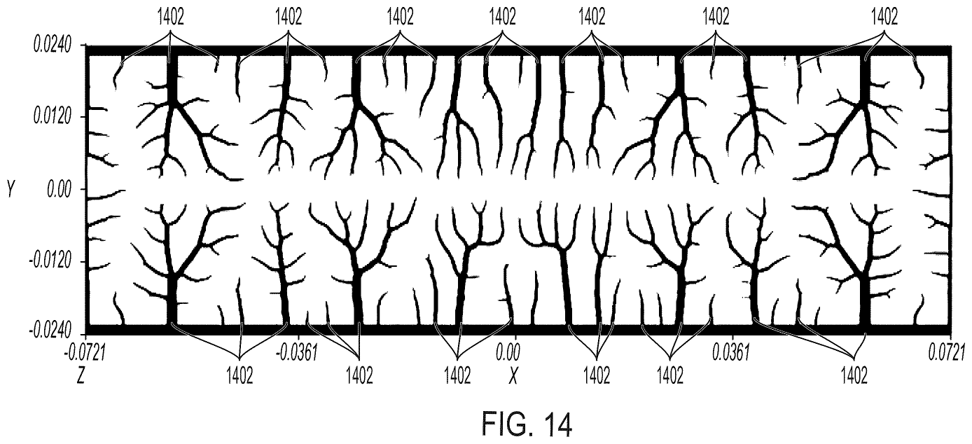

FIG. 14 shows an example of gridlines 1402 according to examples of the present disclosure. For example, one fixed crack pattern observed in the field can be used for the simulations. The crack patterns can be chosen randomly from a library of patterns observed in the field. 100% probability can be assigned that the cell cracks will electrically sever the gridlines they cross, and the number of severed gridlines can be counted after each hailstone impact. This 100% probably can be adjusted as the field data will become available. High-impact events can be physically decoupled; the crack pattern created by the 1st impact will not interfere with the subsequent impact events. That is, each impact event can be treated as a brand-new impact on a pristine solar cell. This latter assumption can be relaxed. The impact event can then be repeated at randomly chosen locations on the cell until a statistically representative number of severed gridlines per hailstone impact is obtained. The same MC simulations can be conducted on topologically optimized gridline designs for comparison. When 100% probability is assigned to cell cracks severing gridlines, there may be little difference between standard metallization and topologically optimized metallization in the number of severed gridlines per hailstone impact. However, as the probability reflecting the field data for standard metallization vs. topologically optimized composite metallization is adjusted, a divergence in performance is expected.

### Optimization Approach and Design Options

According to examples of the present disclosure and to test the above, a small (2 inch×2 inch) cells are fabricated using the standard gridline design with commercial silver paste and a full-size (166 mm×166 mm) cell is fabricated, and both tested to characterize the cell performance as the baseline. The small cells are fabricated using the standard gridline design with MMC paste and the cell performance is characterized to ensure that the cell performance is not compromised by using MMC paste. Topologically optimize gridline design are determined and used for maximum current collection and efficiency, while maintaining same or less silver usage. Loss mechanisms can be incorporated into the model (e.g., Auger and Shockley-Read-Hall recombination) instead of couching loss mechanisms into Rₛₕ. The initial conditions (e.g., dimension and placement of gridlines, width of the separation in the middle of the gridlines, dimension and placement of horizontal connections, etc.) can be varied that are expected to result in numerous design options. The topological optimization appears to be sensitive to the initial condition, leading to many initial condition-dependent solutions. Design options that would maximize efficiency can then be selected. Small (2 inch×2 inch) cells can be fabricated using the gridline design topologically optimized for efficiency with commercial silver paste. The performance to the baseline and MMC paste can be compared. Topologically optimize gridline design can be determined and used that provides for minimum stress, while maintaining same or less silver usage. The initial conditions can be chosen from efficiency optimized structures. The initial conditions (e.g., dimension and placement of gridlines, width of the separation in the middle of the gridlines, dimension and placement of horizontal connections, staggered gridlines, etc.) can be varied that are expected to result in numerous design options. Design options that would maximize crack tolerance can then be selected. Small (2 inch×2 inch) cells using the gridline design topologically optimized for stress minimization with commercial silver paste can then be created and the performance can be compared to the baseline and with MMC paste. Monte Carlo simulations can then be performed. One or more optimal designs can be determined that provides improved or maximum efficiency and stress minimization that leads to least number of electrically “severed” regions. The optimization process can then be repeated to find a balance between potentially competing objective functions and to determine one or more designs that would maximize the crack tolerance for the cells. Small (2 inch×2 inch) cells can be fabricated using the gridline design topologically optimized for efficiency, stress minimization, and crack patterns with commercial silver paste. The performance to the baseline and the MMC paste can then be compared. Glass/glass mini-modules from 166 mm×166 mm, 9-busbar, bifacial p-type Passivated Emitter and Rear Contact (p-PERC) cells can be fabricated and compared to standard gridline design/commercial silver paste with topologically optimized design/MMC paste. For example, four permutations can be considered including two modules constructed from standard gridline design/commercial silver paste, two modules constructed from standard gridline design/MMC paste, two modules constructed from topologically optimized gridline design/commercial paste, and two modules constructed from topologically optimize gridline design/MMC paste. Static/dynamic load test can be performed to simulate the wind load during extreme weather events, while measuring power output. The load test can be combined with thermal cycling to electrically open up the cell cracks and enhance the comparison between standard gridline design/commercial silver paste and topologically optimized design/MMC paste. Hail damage test can be performed and the power degradation measured from the four different permutations of modules.

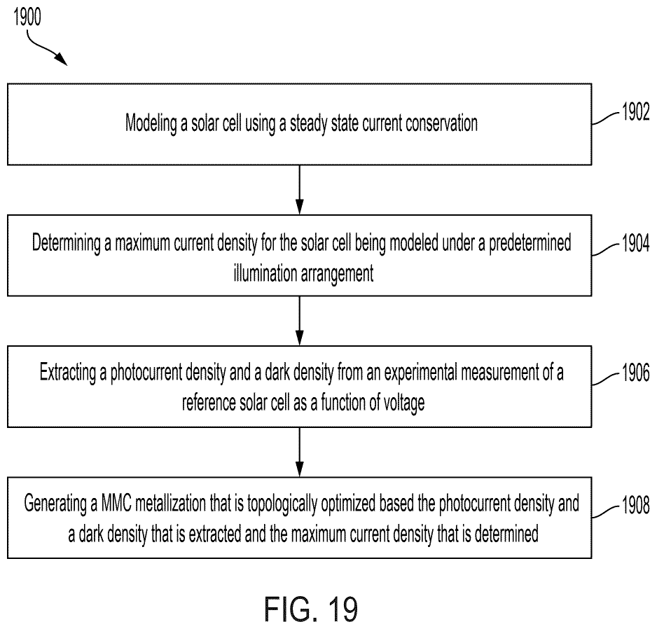

FIG. 19 shows a flowchart for a method to topologically optimize metallization used in solar cells 1900 according to examples of the present disclosure. The method to topologically optimize metallization used in solar cells 1900 comprises modeling a solar cell using a steady state current conservation equation, as in 1902. For example, the metallization is topologically optimized using a structural optimization process with one or more multi-physics constraints. For examples, the metallization is topologically optimized to improve durability and efficiency and to reduce production costs of silicon PV modules. For examples, the metallization is topologically optimized for gridlines and busbars to maximum efficiency, improved tolerance for observed stress, and resilience to cell cracks and crack patterns. For example, the metallization is topologically optimized while maintaining a same or less metal coverage on a cell surface to maximize light absorption and keeping gridline dimensions above the minimum screen-printable features. For example, the metallization comprises surface-functionalized, carbon nanotubes (CNTs). For examples, the multi-physics constraints comprise one or more governing device physics parameters and one or more physical parameters. For example, the one or more physical parameters comprise a current density representing minority carrier generation rate, a minority carrier recombination rate, single diode parameters comprising a series and shunt resistance, conductance in emitter. For example, the structural optimization process comprises a solid isotropic material with penalization (SIMP) density model and a gradient-based method of moving asymptotes (MMA) solver. For example, the MMA solver maximizes solar power generated by spatially manipulating a silver volume fraction. For example, the silver volume fraction varies between a pure silicon state and a pure silver state to form an optimized silver-silicon alloy structure. For example, the pure silicon state is set equal zero and the pure silver state is set equal to one. For example, the SIMP density model comprises material and structural parameters. For example, the material and structural parameters comprise electrical conductivity, relative permittivity, and material thickness that vary as a function of one. For example, the structural optimization process comprises a step-function filter to extract discrete silver and silicon domains as a binary choice. For example, the structural optimization process comprises using an optimized gridline structure in simulation to extract cell performance. For example, the metallization comprises a metal matrix composite (MMC).

The method to topologically optimize metallization used in solar cells 1900 continues by determining a maximum current density for the solar cell being modeled under a predetermined illumination arrangement, as in 1904. The method to topologically optimize metallization used in solar cells 1900 continues by extracting a photocurrent density and a dark density from an experimental measurement of a reference solar cell as a function of voltage, as in 1906. The method to topologically optimize metallization used in solar cells 1900 continues by generating a metallization that is topologically optimized based the photocurrent density and a dark density that is extracted and the maximum current density that is determined, as in 1908.

In some examples the method to topologically optimize metallization used in solar cells 1900 can further comprise screen-printing and firing the optimized gridline structure on solar cells, wherein the solar cells comprise p-type bifacial passivated emitter and rear contact (PERC) solar cells and n-type cells Tunnel Oxide Passivated Contact (TOPCon) solar cells.

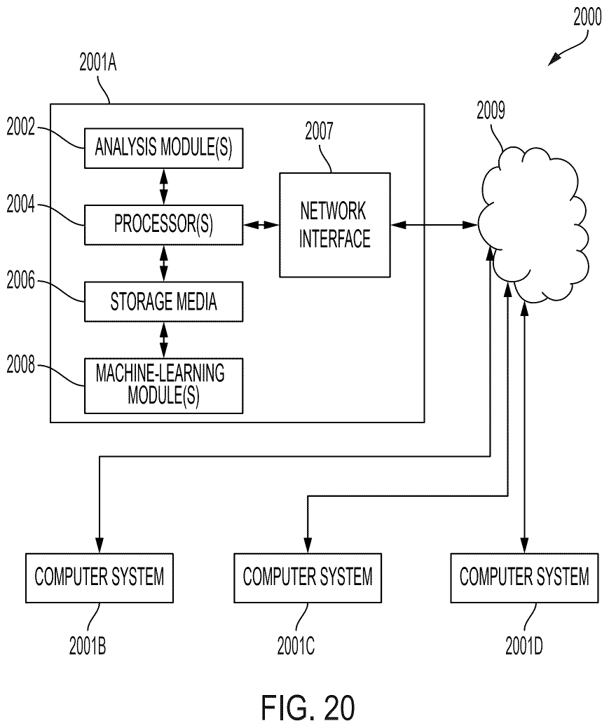

In some embodiments, any of the methods of the present disclosure may be executed by a computing system. FIG. 20 illustrates an example of such a computing system 2000, in accordance with some embodiments. The computing system 2000 may include a computer or computer system 2001A, which may be an individual computer system 2001A or an arrangement of distributed computer systems. The computer system 2001A includes one or more analysis module(s) 2002 configured to perform various tasks according to some embodiments, such as one or more methods disclosed herein. To perform these various tasks, the analysis module 2002 executes independently, or in coordination with, one or more processors 2004, which is (or are) connected to one or more storage media 2006. The processor(s) 2004 is (or are) also connected to a network interface 2007 to allow the computer system 2001A to communicate over a data network 2009 with one or more additional computer systems and/or computing systems, such as 2001B, 2001C, and/or 2001D (note that computer systems 2001B, 2001C and/or 2001D may or may not share the same architecture as computer system 2001A, and may be located in different physical locations, e.g., computer systems 2001A and 2001B may be located in a processing facility, while in communication with one or more computer systems such as 2001C and/or 2001D that are located in one or more data centers, and/or located in varying countries on different continents). A processor can include a microprocessor, microcontroller, processor module or subsystem, programmable integrated circuit, programmable gate array, or another control or computing device.

The storage media 2006 can be implemented as one or more computer-readable or machine-readable storage media. The storage media 2006 can be connected to or coupled with a machine learning module(s) 2008. Note that while in the example embodiment of FIG. 20 storage media 2006 is depicted as within computer system 2001A, in some embodiments, storage media 2006 may be distributed within and/or across multiple internal and/or external enclosures of computing system 2001A and/or additional computing systems. Storage media 2006 may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories, magnetic disks such as fixed, floppy and removable disks, other magnetic media including tape, optical media such as compact disks (CDs) or digital video disks (DVDs), BLURAY® disks, or other types of optical storage, or other types of storage devices. Note that the instructions discussed above can be provided on one computer-readable or machine-readable storage medium, or alternatively, can be provided on multiple computer-readable or machine-readable storage media distributed in a large system having possibly plural nodes. Such computer-readable or machine-readable storage medium or media is (are) considered to be part of an article (or article of manufacture). An article or article of manufacture can refer to any manufactured single component or multiple components. The storage medium or media can be located either in the machine running the machine-readable instructions or located at a remote site from which machine-readable instructions can be downloaded over a network for execution.

It should be appreciated that computing system 2000 is only one example of a computing system, and that computing system 2000 may have more or fewer components than shown, may combine additional components not depicted in the example embodiment of FIG. 20, and/or computing system 2000 may have a different configuration or arrangement of the components depicted in FIG. 20. The various components shown in FIG. 20 may be implemented in hardware, software, or a combination of both hardware and software, including one or more signal processing and/or application specific integrated circuits.

Further, the steps in the processing methods described herein may be implemented by running one or more functional modules in an information processing apparatus such as general-purpose processors or application specific chips, such as ASICs, FPGAs, PLDs, or other appropriate devices. These modules, combinations of these modules, and/or their combination with general hardware are all included within the scope of protection of the invention.

Models and/or other interpretation aids may be refined in an iterative fashion; this concept is applicable to embodiments of the present methods discussed herein. This can include the use of feedback loops executed on an algorithmic basis, such as at a computing device (e.g., computing system 2000, FIG. 20), and/or through manual control by a user who may make determinations regarding whether a given step, action, template, model, or set of curves has become sufficiently accurate for the evaluation of the signal(s) under consideration.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. Moreover, the order in which the elements of the methods are illustrated and described may be re-arranged, and/or two or more elements may occur simultaneously. The embodiments were chosen and described in order to best explain the principles of the invention and its practical applications, to thereby enable others skilled in the art to best utilize the invention and various embodiments with various modifications as are suited to the particular use contemplated.

What is claimed is:

1. A method to topologically optimize metallization used in solar cells, the method comprising:
modeling a solar cell using a steady state current conservation equation;
determining a maximum current density for the solar cell being modeled under a predetermined illumination arrangement;
extracting a photocurrent density and a dark density from an experimental measurement of a reference solar cell as a function of voltage; and
generating a metallization that is topologically optimized based the photocurrent density and a dark density that is extracted and the maximum current density that is determined.

2. The method of claim 1, wherein the metallization is topologically optimized using a structural optimization process with one or more multi-physics constraints.

3. The method of claim 1, wherein the metallization is topologically optimized to improve durability and efficiency and to reduce production costs of silicon PV modules.

4. The method of claim 1, wherein the metallization is topologically optimized for gridlines and busbars to maximum efficiency, improved tolerance for observed stress, and resilience to cell cracks and crack patterns.

5. The method of claim 1, wherein the metallization is topologically optimized while maintaining a same or less metal coverage on a cell surface to maximize light absorption and keeping gridline dimensions above the minimum screen-printable features.

6. The method of claim 1, wherein the metallization comprises surface-functionalized, carbon nanotubes (CNTs).

7. The method of claim 2, wherein the multi-physics constraints comprise one or more governing device physics parameters and one or more physical parameters.

8. The method of claim 7, wherein the one or more physical parameters comprise a current density representing minority carrier generation rate, a minority carrier recombination rate, single diode parameters comprising a series and shunt resistance, conductance in emitter.

9. The method of claim 2, wherein the structural optimization process comprises a solid isotropic material with penalization (SIMP) density model and a gradient-based method of moving asymptotes (MMA) solver.

10. The method of claim 9, wherein the MMA solver maximizes solar power generated by spatially manipulating a silver volume fraction.

11. The method of claim 10, wherein the silver volume fraction varies between a pure silicon state and a pure silver state to form an optimized silver-silicon alloy structure.

12. The method of claim 11, wherein the pure silicon state is set equal zero and the pure silver state is set equal to one.

13. The method of claim 9, wherein the SIMP density model comprises material and structural parameters.

14. The method of claim 9, wherein the material and structural parameters comprise electrical conductivity, relative permittivity, and material thickness that vary as a function of one.

15. The method of claim 2, wherein the structural optimization process comprises a step-function filter to extract discrete silver and silicon domains as a binary choice.

16. The method of claim 2, wherein the structural optimization process comprises using an optimized gridline structure in simulation to extract cell performance.

17. The method of claim 16, further comprising screen-printing and firing the optimized gridline structure on solar cells, wherein the solar cells comprise p-type bifacial passivated emitter and rear contact (PERC) solar cells and n-type cells Tunnel Oxide Passivated Contact (TOPCon) solar cells.

18. The method of claim 1, wherein the metallization comprises a metal matrix composite (MMC).

19. A computer system comprising:
a hardware processor; and
a non-transitory computer readable storage medium storing instructions that when executed by the hardware processor perform a method to topologically optimize metallization used in solar cells, the method comprising:
modeling a solar cell using a steady-state current conservation equation;
determining a maximum current density for the solar cell being modeled under a predetermined illumination arrangement;
extracting a photocurrent density and a dark density from an experimental measurement of a reference solar cell as a function of voltage; and
generating a metallization that is topologically optimized based the photocurrent density and a dark density that is extracted and the maximum current density that is determined.

20. A solar cell comprising:
topologically optimized metallization for gridlines and busbars to maximum efficiency, improved tolerance for observed stress, and resilience to cell cracks and crack patterns.
